(19) United States
(12) Patent Application Publication
(10) Pub. No.: US 2015/0098074 A1
(43) Pub. Date: Apr. 9, 2015

(54) STAGE BRAKING SYSTEM FOR A MOTOR

(71) Applicant: NIKON CORPORATION, Tokyo (JP)

(72) Inventors: Matthew Rosa, Fremont, CA (US); Michael Binnard, Belmont, CA (US); Chetan Mahadeswaraswamy, San Francisco, CA (US); W. Thomas Novak, Redwood City, CA (US)

(21) Appl. No.: 14/511,076

(22) Filed: Oct. 9, 2014

Related U.S. Application Data
(60) Provisional application No. 61/888,926, filed on Oct. 9, 2013.
(60) Provisional application No. 61/912,645, filed on Dec. 6, 2013.

(51) Int. Cl. G03F 7/20

(52) U.S. Cl. CPC G03F 7/70775; G03F 7/70725
USPC 355/72

(57) ABSTRACT

A stage assembly that moves a device includes a stage that retains the device, a stage mover that moves the stage, a measurement system that provides a measurement signal that relates to the position or movement of the stage, and a control system that control the stage mover. The control system can use an estimator to estimate the position of the stage in the event the measurement signal is lost. Alternatively, the control system can be used to urge the stage against a base assembly when the measurement signal is lost to inhibit the movement of the stage.

### CROSS-REFERENCE TO RELATED APPLICATION

This application claims priority on U.S. Provisional Application Ser. No. 61/888,926 filed on Oct. 9, 2013 and entitled “OPEN-LOOP STAGE BRAKING FOR PLANAR MOTOR”. This application also claims priority on U.S. Provisional Application Ser. No. 61/912,645 filed on Dec. 6, 2013 and entitled “STAGE BRAKING SYSTEM FOR PLANAR MOTOR”. As far as is permitted, the contents of U.S. Provisional Application Ser. Nos. 61/888,926 and 61/912,645 are incorporated herein by reference.

### BACKGROUND

Exposure apparatuses are commonly used to transfer images from a reticle onto a semiconductor wafer during semiconductor processing. A typical exposure apparatus includes an illumination source, a reticle stage assembly that retains a reticle, a lens assembly, a wafer stage assembly that retains a semiconductor wafer, a metrology system that monitors the position of the stage assemblies, and a control system that controls the stage assemblies based on the position information from the metrology system. Typically, the wafer stage assembly includes a wafer stage base, a wafer stage that retains the wafer, and a wafer stage mover assembly that precisely positions the wafer stage and the wafer. Somewhat similarly, the reticle stage assembly includes a reticle stage base, a reticle stage that retains the reticle, and a reticle stage mover assembly that precisely positions the reticle stage and the reticle.

In various exposure apparatuses, the wafer stage mover assembly and/or the reticle stage mover assembly use a planar motor that includes a conductor array and a magnet array that interacts with the conductor array to precisely move and position the stage. During use, errors can occur in the metrology system, and, thus, situations can occur where the stage position is no longer known. With no feedback regarding the position, the control system has difficulty controlling the position of the stage assemblies.

### SUMMARY

The present invention is directed toward a method for controlling a stage mover that moves a stage along a desired trajectory. In certain embodiments, the method comprises the steps of (i) monitoring a position of the stage at a plurality of alternative time instances with a measurement system that generates a measurement signal for each time instance; (ii) determining the position and a velocity of the stage at each of the time instances using the measurement signal for each time instance with a control system; (iii) controlling the stage mover with the control system, the control system generating a force command and a torque command based on the determined position and velocity information and the desired trajectory; and (iv) in the event of the loss of the measurement signal, estimating an estimated position and an estimated velocity of the stage with the control system using the most recent determined position and velocity information, as well as the most recent force and torque commands. With this design, an open loop controller can be used to control the stage mover to quickly and safely arrest the motion of the stage when accurate position sensor data is unavailable.

Additionally, in one embodiment, the step of estimating includes the step of using the equations F=(M×A) and T=(I×alpha) to calculate the estimated position and the estimated velocity, where F is the force command, M is the mass of the stage, A is the acceleration of the stage, T is the torque command, I is the inertia of the stage, and alpha is the angular acceleration of the stage.

Further, in one embodiment, the method can further comprise the step of using an observer to create an accurate model of M and I during normal control of the stage. In such embodiment, the step of estimating includes using the accurate model of M and I to calculate the estimated position and the estimated velocity of the stage in the event of the loss of the measurement signal.

Still further, in one embodiment, the method can further comprise the step of, in the event of loss of measurement signal, using the estimated position and the estimated velocity of the stage to generate estimated force and torque commands with the control system that will stop the movement of stage.

Further, in one embodiment, the method can include the step of controlling the stage mover to urge the stage against the reaction assembly when the measurement signal is lost.

Additionally, the present invention is directed to a method for moving a stage along a desired trajectory relative to a base assembly. In one embodiment, the method includes the steps of: coupling a stage mover to the stage and the base assembly, the stage mover being adapted to move the stage with six degrees of freedom relative to the base assembly; generating a measurement signal with a measurement system that monitors the position/movement of the stage; and creating a vacuum between the stage and the base assembly when the measurement signal is lost to inhibit the movement of the stage.

Additionally, the method can include the step of closing a coil circuit of the stage mover to provide coil/eddy current braking of the stage.

The present invention is also directed to a stage assembly for moving a device along a desired trajectory. In this embodiment, the stage assembly can include: a stage that retains the device; a base assembly; a stage mover that is adapted to move the stage with six degrees of freedom relative to the base assembly; generating a measurement signal with a measurement system that generates a measurement signal that relates to the movement or position of the stage; and a fluid source that creates a vacuum between the stage and the base assembly when the measurement signal is lost to inhibit the movement of the stage.

As provided herein, the stage mover can include a first mover array that is coupled to the stage and a second mover array that is coupled to the base assembly. Further, the stage can include a flexible skirt that is positioned around and encircles the first mover array.

Moreover, the stage can include an enlarged contact area that selectively engages the base assembly to provide a relatively large contact area to inhibit relative movement between the stage and the base assembly.

In one embodiment, the base assembly includes a reaction mass.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a schematic illustration of an exposure apparatus having features of the present invention;

FIG. 2 is a perspective view of an embodiment of a stage assembly that can be included as part of the exposure apparatus of FIG. 1;

FIG. 3 is a schematic illustration of an embodiment of a control system usable as part of the stage assembly of FIG. 2;

FIG. 4 is a schematic illustration of another embodiment of a control system usable as part of the stage assembly of FIG. 2;

FIG. 5A is a flow chart that outlines a process for manufacturing a device in accordance with the present invention;

FIG. 5B is a flow chart that outlines device processing in more detail;

FIG. 6A is a simplified cut-away view of a portion of the stage assembly in an elevated position;

FIG. 6B is a simplified cut-away view of the portion of the stage assembly of FIG. 6A in a stopped position;

FIG. 7 is a simplified cut-away view of another embodiment of a portion of the stage assembly in the stopped position;

FIG. 8 is a simplified enlarged cut-away view of a portion of another embodiment of the stage assembly in the stopped position;

FIG. 9 is a simplified cut-away view of still another embodiment of a portion of the stage assembly in the stopped position;

FIG. 10A and 10B are simplified cut-away views of a portion of yet another embodiment of a stage assembly having features of the present invention;

FIG. 11 is a perspective view of an embodiment of a stage assembly having features of the present invention;

FIG. 12 is a simplified top view of another embodiment of a stage assembly having features of the present invention; and

FIG. 13 is a simplified side view of a stage mover having features of the present invention.

### DESCRIPTION

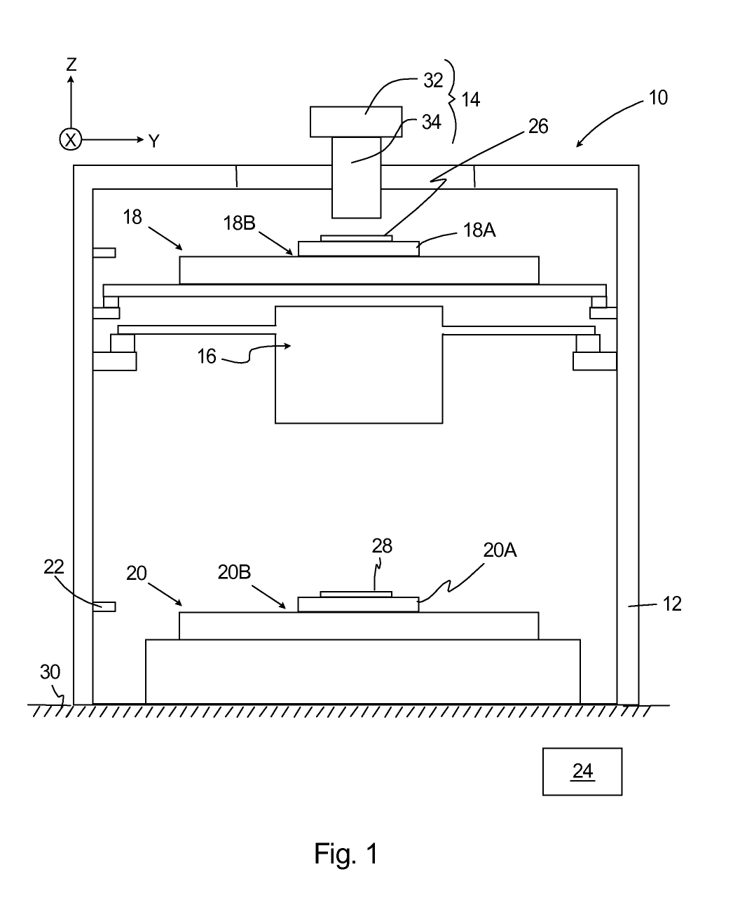

FIG. 1 is a schematic illustration of a precision assembly, namely an exposure apparatus 10 having features of the present invention. The exposure apparatus 10 includes an apparatus frame 12, an illumination system 14 (irradiation apparatus), an optical assembly 16 (lens assembly), a reticle stage assembly 18, a wafer stage assembly 20, a measurement system 22, and a control system 24. The design of the components of the exposure apparatus 10 can be varied to suit the design requirements of the exposure apparatus 10.

A number of Figures include an orientation system that illustrates an X axis, a Y axis that is orthogonal to the X axis, and a Z axis that is orthogonal to the X and Y axes. It should be understood that the orientation system is merely for reference and can be varied. For example, the X axis can be switched with the Y axis and/or the exposure apparatus 10 can be rotated. Moreover, it should be noted that any of these axes can also be referred to as the first, second, and/or third axes.

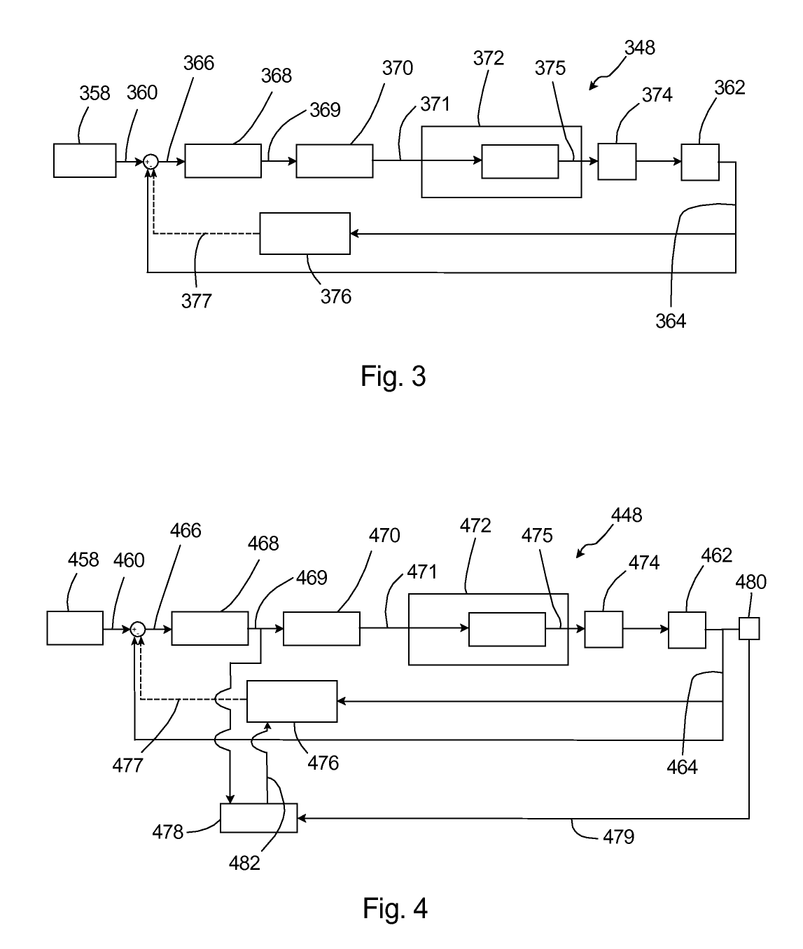

As an overview, as described in greater detail herein below, the control system 24 can include an open-loop control system that is designed to effectively control the movement of a stage, i.e. a reticle stage 18A and/or a wafer stage 20A, even when the measurement system 22 is unable to provide position information of the stage for any reason. In one embodiment, the control system 24 can utilize and/or implement an open-loop stage braking system that estimates the position and velocity of the stage based on known or observed information, e.g., using an estimator 376 (illustrated in FIG. 3) or an estimator 476 (illustrated in FIG. 4) in conjunction with an observer 478 (illustrated in FIG. 4), and then calculates the necessary force and/or torque that is required to effectively arrest the motion of the stage through actuation of a stage mover. This will prevent the situation of a run-away stage in the event of a lost measurement signal.

Stated in another fashion, with the high velocities and large moving mass in current lithography systems, the stage can move a large distance before stopping after a loss of servo control (e.g. loss of measurement signal) if the motion of the stage is not arrested as quickly as desired. For example, in lithography systems with planar motor wafer stages which have no physical hard stops, in the event of loss of servo control, the stage can literally fly off the stage base or crash into sensitive components if motion of the stage is not quickly arrested. The present invention includes means for arresting the motion of the stage to inhibit the crashing of the stage until the location of the stage can again be determined.

Accordingly, one advantage of the present invention is that through open-loop control actuation of the stage mover, the stage can be brought to a halt nearly as fast as would be possible under full feedback control. This greatly mitigates the risk of the stage running into something important when metrology is lost.

The exposure apparatus 10 provided herein is particularly useful as a lithographic device that transfers a pattern (not shown) of an integrated circuit from a reticle 26 onto a semiconductor wafer 28. The exposure apparatus 10 mounts to a mounting base 30, e.g., the ground, a base, a floor or some other supporting structure.

There are a number of different types of lithographic devices. For example, the exposure apparatus 10 can be used as a scanning type photolithography system that exposes the pattern from the reticle 26 onto the wafer 28 with the reticle 26 and the wafer 28 moving synchronously. Alternatively, the exposure apparatus 10 can be a step-and-repeat type photolithography system that exposes the reticle 26 while the reticle 26 and the wafer 28 are both stationary.

However, the use of the exposure apparatus 10 and stage assemblies provided herein is not limited to a photolithography system for semiconductor manufacturing. The exposure apparatus 10, for example, can be used as an LCD photolithography system that exposes a liquid crystal display device pattern onto a rectangular glass plate or a photolithography system for manufacturing a thin film magnetic head. Further, the present invention can also be applied to a proximity photolithography system that exposes a mask pattern by closely locating a mask and a substrate without the use of a lens assembly. Additionally, the present invention provided herein can be used in other devices, including other semiconductor processing equipment, elevators, machine tools, metal cutting machines, inspection machines and disk drives.

The apparatus frame 12 is rigid and supports various components of the exposure apparatus 10. The design of the apparatus frame 12 can be varied to suit the design requirements of the rest of the exposure apparatus 10. The apparatus frame 12 illustrated in FIG. 1 supports the optical assembly 16, the reticle stage assembly 18, the wafer stage assembly 20, and the illumination system 14 above the mounting base 30.

The illumination system 14 includes an illumination source 32 and an illumination optical assembly 34. The illumination source 32 emits a beam (irradiation) of light energy. The illumination optical assembly 34 guides the beam of light energy from the illumination source 32 to the optical assembly 16. The beam of light energy selectively illuminates different portions of the reticle 26 and exposes the wafer 28. In FIG. 1, the illumination source 32 is illustrated as being supported above the reticle stage assembly 18. Alternatively, the illumination source 32 can be secured to one of the sides of the apparatus frame 12 and the energy beam from the illumination source 32 can be directed to above the reticle stage assembly 18 with the illumination optical assembly 34.

The illumination source 32 can be a g-line source (436 nm), an i-line source (365 nm), a KrF excimer laser (248 nm), an ArF excimer laser (193 nm), a F₂ laser (157 nm), or an EUV source (13.5 nm). Alternatively, the illumination source 32 can generate charged particle beams such as an x-ray or an electron beam. For instance, in the case where an electron beam is used, thermionic emission type lanthanum hexaboride (LaB₆) or tantalum (Ta) can be used as a cathode for an electron gun. Furthermore, in the case where an electron beam is used, the structure could be such that either a mask is used or a pattern can be directly formed on a substrate without the use of a mask.

The optical assembly 16 projects and/or focuses the light passing through the reticle 26 to the wafer 28. Depending upon the design of the exposure apparatus 10, the optical assembly 16 can magnify or reduce the image illuminated on the reticle 26. The optical assembly 16 need not be limited to a reduction system. It could also be a 1× or magnification system.

The reticle stage assembly 18 holds and positions the reticle 26 relative to the optical assembly 16 and the wafer 28. In FIG. 1, the reticle stage assembly 18 includes the reticle stage 18A that retains the reticle 26, and a reticle stage mover assembly 18B that positions the reticle stage 18A and the reticle 26. The reticle stage mover assembly 18B can be designed to move the reticle 26 along the X and Y axes, and about the Z axis. Alternatively, the reticle stage mover assembly 18B can be designed to move the reticle 26 along the X, Y and Z axes, and about the X, Y and Z axes.

Somewhat similarly, the wafer stage assembly 20 holds and positions the wafer 28 with respect to the projected image of the illuminated portions of the reticle 26. In FIG. 1, the wafer stage assembly 20 includes the wafer stage 20A that retains the wafer 28, and a wafer stage mover assembly 20B that positions the wafer stage 20A and the wafer 28. The wafer stage mover assembly 20B can be designed to move the wafer 28 along the X and Y axes, and about the Z axis. Alternatively, the wafer stage mover assembly 20B can be designed to move the wafer 28 along the X, Y and Z axes, and about the X, Y and Z axes. In this embodiment, the wafer 28 can be scanned while the wafer stage assembly 20 moves the wafer 28 along the Y axis.

The measurement system 22 monitors the position and/or movement of the reticle 26 and the wafer 28 relative to the optical assembly 16 or some other reference. With this information, the control system 24 can control the reticle stage assembly 18 to precisely position the reticle 26 and the wafer stage assembly 20 to precisely position the wafer 28. For example, the measurement system 22 can utilize multiple laser interferometers, encoders, autofocus systems, and/or other measuring devices. In certain embodiments, the measurement system 22 includes one or more interferometers and one or more encoders.

The control system 24 is electrically connected to the reticle stage assembly 18, the wafer stage assembly 20, and the measurement system 22. The control system 24 receives information from the measurement system 22 and controls the stage assemblies 18, 20 to precisely position the reticle 26 and the wafer 28. The control system 24 can include one or more processors and circuits, and can be programmed to perform the control steps provided herein.

As described above, a photolithography system according to the above described embodiments can be built by assembling various subsystems, including each element listed in the appended claims, in such a manner that prescribed mechanical accuracy, electrical accuracy, and optical accuracy are maintained. In order to maintain the various accuracies, prior to and following assembly, every optical system is adjusted to achieve its optical accuracy. Similarly, every mechanical system and every electrical system are adjusted to achieve their respective mechanical and electrical accuracies. The process of assembling each subsystem into a photolithography system includes mechanical interfaces, electrical circuit wiring connections and air pressure plumbing connections between each subsystem. Needless to say, there is also a process where each subsystem is assembled prior to assembling a photolithography system from the various subsystems. Once a photolithography system is assembled using the various subsystems, a total adjustment is performed to make sure that accuracy is maintained in the complete photolithography system. Additionally, it is desirable to manufacture an exposure system in a clean room where the temperature and cleanliness are controlled.

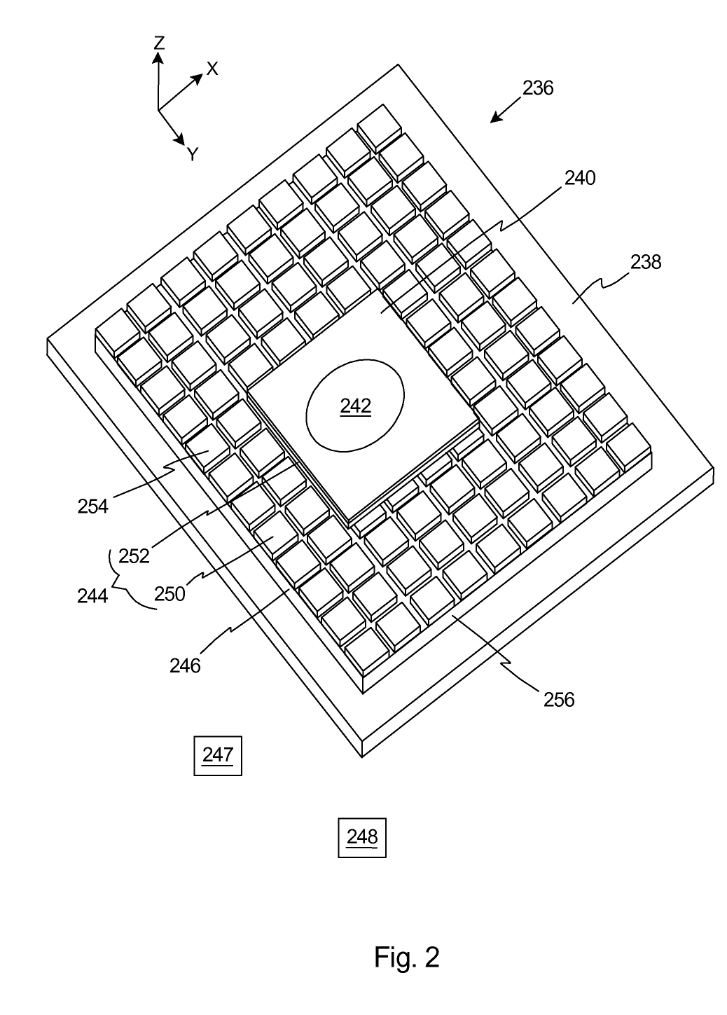

FIG. 2 is a perspective view of an embodiment of a stage assembly 236 having features of the present invention. In various applications, the stage assembly 236 can be utilized as the reticle stage assembly 18 and/or the wafer stage assembly 20 of the exposure apparatus 10 illustrated above in FIG. 1. Alternatively, the stage assembly 236 can be used to move or position another type of device or workpiece.

As illustrated in this embodiment, the stage assembly 236 includes a stage base 238, a stage 240 that retains a device 242, a stage mover 244, a countermass reaction assembly 246 (also referred to herein simply as a “reaction assembly” or “reaction mass”), a measurement system 247 (illustrated as a box), and a control system 248 (illustrated with a box). In certain embodiments, the stage base 238 and the reaction assembly 246 can be referred to as a base assembly. The design of each of these components can be varied to suit the design requirements of the stage assembly 236. In certain applications, the stage assembly 236 can be positioned above a mounting base, e.g., the mounting base 30 (illustrated in FIG. 1). The stage mover 244 precisely moves the stage 240 and the device 242 relative to the stage base 238 and the reaction assembly 246. In some embodiments, the stage assembly 236 can further include a temperature controller (not illustrated) that controls the temperature of the stage mover 244 and/or the reaction assembly 246 under the direction of the control system 248.

The stage assembly 236 is particularly useful for precisely positioning the device 242 during a manufacturing and/or an inspection process. The type of device 242 positioned and moved by the stage assembly 236 can be varied. For example, the device 242 can be a semiconductor wafer, and the stage assembly 236 can be used as part of the exposure apparatus 10 for precisely positioning the semiconductor wafer during manufacturing of the semiconductor wafer. Alternatively, for example, the stage assembly 236 can be used to move other types of devices during manufacturing and/or inspection, to move a device under an electron microscope (not shown), or to move a device during a precision measurement operation (not shown).

The stage base 238 supports a portion of the stage assembly 236 above the mounting base 30. In the embodiment illustrated herein, the stage base 238 is rigid and generally rectangular shaped.

As noted above, the stage 240 retains the device 242. Further, the stage 240 is precisely moved by the stage mover 244 to precisely position the device 242. In the embodiment illustrated herein, the stage 240 is generally rectangular shaped and includes a device holder (not shown) for retaining the device 242. The device holder can be a vacuum chuck, an electrostatic chuck, or some other type of clamp.

The stage 240 can be maintained spaced apart from (e.g., above) the reaction assembly 246 with the stage mover 244 if the stage mover 244 is a six degree of freedom mover that moves the stage 240 relative to the reaction assembly 246 with six degrees of freedom. In this embodiment, the stage mover 244 functions as a magnetic type bearing that levitates the stage 240. Alternatively, for example, the stage 240 can be partly or fully supported relative to the reaction assembly 246 with a stage bearing (not shown), e.g., a vacuum preload type fluid bearing. For example, the bottom of the stage 240 can include a plurality of spaced apart fluid outlets (not shown), and a plurality of spaced apart fluid inlets (not shown). In this example, pressurized fluid (not shown) can be released from the fluid outlets towards the reaction assembly 246 and a vacuum can be pulled in the fluid inlets to create a vacuum preload type, fluid bearing between the stage 240 and the reaction assembly 246. In this embodiment, the stage bearing allows for motion of the stage 240 relative to the reaction assembly 246 along the X axis, along the Y axis and about the Z axis.

The stage mover 244 controls and adjusts the position of the stage 240 and the device 242 relative to the reaction assembly 246 and the stage base 238. For example, the stage mover 244 can be a planar motor that moves and positions the stage 240 along the X axis, along the Y axis and about the Z axis (“three degrees of freedom” or “the planar degrees of freedom”). Further, in certain embodiments, the stage mover 244 can also be controlled to move the stage 240 along Z axis and about the X and Y axes. With this design, the stage mover 244 is a six degree of freedom mover.

In the embodiments illustrated herein, the stage mover 244 includes a conductor array 250, and an adjacent magnet array 252 that interacts with the conductor array 250. In FIG. 2, the conductor array 250 is coupled to the reaction assembly 246, and the magnet array 252 is secured to the stage 240. Alternatively, in one embodiment, the conductor array 250 can be coupled to the stage 240 and the magnet array 252 can be coupled to the reaction assembly 246. As provided herein, the array secured to the stage 240 can be referred to as the moving component (or mover) of the stage mover 244, and the array secured to the reaction assembly 246 can be referred to as the reaction component (or stator) of the stage mover 244.

In certain embodiments, the conductor array 250 can include a plurality of coil units 254. In one such embodiment, each coil unit 254 can include one or more coil(s) (not shown) that is oriented to generate a force along the X-axis and/or along the Y-axis when current is directed to the conductor array 250. Each coil can be made of a metal such as copper or any substance or material responsive to electrical current and capable of creating a magnetic field such as superconductors.

The design and number of coil units 254 in the conductor array 250 can vary according to the performance and movement requirements of the stage mover 244. For example, in the embodiment illustrated in FIG. 2, the conductor array 250 includes one hundred eight coil units 254 that are arranged in a generally rectangular twelve-by-nine array. Additionally, the individual coil units 254 can be arranged such that a plurality of Y-coil units and a plurality of X-coil units are positioned and/or arranged in an alternating pattern in both the X-direction and the Y-direction. Thus, in such embodiment, the conductor array 250 includes fifty-four X-coil units 254 and fifty-four Y-coil units 254 that are arranged in an alternating pattern in both the X-direction and the Y-direction.

Further, the magnet array 252 can include one or more magnets (not illustrated) that interact with the plurality of coil units 254. The design of the magnet array 252 and the number of magnets in the magnet array 252 can be varied to suit the design requirements of the stage mover 244. In some embodiments, each magnet can be made of a permanent magnetic material such as NdFeB.

Electrical current (not shown) is supplied to the coil units 254 by the control system 248. The electrical current in the coil units 254 interacts with the magnetic field(s) of the one or more magnets in the magnet array 252. This causes a force (Lorentz type force) between the coil units 254 and the magnets that can be used to move the stage 240 relative to the stage base 238.

The reaction assembly 246 counteracts, reduces and/or minimizes the influence of the reaction forces from the stage mover 244 on the position of the stage base 238 relative to the mounting base 30. This minimizes the distortion of the stage base 238 and improves the positioning performance of the stage assembly 236. Further, for an exposure apparatus 10, this allows for more accurate positioning of the semiconductor wafer.

As provided above, in the embodiment illustrated in FIG. 2, the conductor array 250 of the stage mover 244 is coupled to the reaction assembly 246. With this design, the reaction forces generated by the stage mover 244 are transferred to the reaction assembly 246. As a result thereof, when the stage mover 244 applies a force to move the stage 240, an equal and opposite reaction force is applied to the reaction assembly 246.

In FIG. 2, the reaction assembly 246 includes a generally rectangular shaped countermass 256, which can be maintained above the stage base 238 with a reaction bearing (not shown), e.g. a vacuum preload type fluid bearing. For example, the bottom of the countermass 256 of the reaction assembly 246 can include a plurality of spaced apart fluid outlets (not shown), and a plurality of spaced apart fluid inlets (not shown). Pressurized fluid (not shown) can be released from the fluid outlets towards the stage base 238 and a vacuum can be pulled in the fluid inlets to create a vacuum preload type, fluid bearing between the stage base 238 and the countermass 256. In this embodiment, the reaction bearing allows for motion of the reaction assembly 246 relative to the stage base 238 along the X axis, along the Y axis and about the Z axis. Alternatively, for example, the reaction bearing can be a magnetic type bearing, or a roller bearing type assembly.

With this design, through the principle of conservation of momentum, (i) movement of the stage 240 with the stage mover 244 along the X axis in a first X direction, generates an equal but opposite X reaction force that moves the reaction assembly 246 in a second X direction that is opposite the first X direction along the X axis; (ii) movement of the stage 240 with the stage mover 244 along the Y axis in a first Y direction, generates an equal but opposite Y reaction force that moves the reaction assembly 246 in a second Y direction that is opposite the first Y direction along the Y axis; and (iii) movement of the stage 240 with the stage mover 244 about the Z axis in a first theta Z direction, generates an equal but opposite theta Z reaction force (torque) that moves the reaction assembly 246 in a second theta Z direction that is opposite the first theta Z direction about the Z axis.

The design of the reaction assembly 246 can be varied to suit the design requirements of the stage assembly 236. In certain embodiments, the ratio of the mass of the reaction assembly 246 to the mass of the stage 240 is relatively high. This will minimize the movement of the reaction assembly 246 and minimize the required travel of the reaction assembly 246. A suitable ratio of the mass of the reaction assembly 246 to the mass of the stage 240 is between approximately 5:1 and 20:1. A larger mass ratio is better, but is limited by the physical size of the reaction assembly 246.

In one embodiment, the reaction assembly 246 is made from a non-electrically conductive, non-magnetic material, such as low electrical conductivity stainless steel or titanium, or non-electrically conductive plastic or ceramic.

Additionally, a trim mover (not shown) can be used to adjust the position of the reaction assembly 246 relative to the stage base 238. For example, the trim mover can include one or more rotary motors, voice coil motors, linear motors, electromagnetic actuators, or other type of actuators.

The measurement system 247 monitors a position of the stage 240 relative to the stage base 238, relative to the reaction assembly 246 and/or relative to some other reference. For example, when the stage assembly 236 is utilized as part of an exposure apparatus, e.g., the exposure apparatus 10 illustrated in FIG. 1, the measurement system 247 can be used to monitor the position and movement of the reticle stage 18A (illustrated in FIG. 1) and/or the wafer stage 20A (illustrated in FIG. 1) relative to the optical assembly 16 (illustrated in FIG. 1) or some other reference.

Further, in some embodiments, the measurement system 247 can be designed to monitor the position of the stage 240 at a plurality of discrete, alternative time instances, with a separate measurement signal being generated by the measurement system 247 based on the measured position of the stage 240 for each time instance. Additionally and/or alternatively, the measurement system 247 can be designed to continuously monitor the position of the stage 240. It should be appreciated that in embodiments where the measurement system 247 monitors the position of the stage 240 at discrete, alternative time instances, such time instances can be very close together, e.g., once every 100 microseconds or once every 200 microseconds, or any other suitable increment of time, or varying increments of time, such that the monitoring of the position of the stage 240 provided by the measurement system 247 is substantially continuous.

In alternative embodiments, the measurement system 247 can utilize multiple laser interferometers, encoders, autofocus systems, and/or other measuring devices.

The control system 248 is electrically connected to, and directs and controls electrical current to the coil units 254 of the stage mover 244 to precisely position the stage 240, and, thus, the device 242. More particularly, in certain applications, the control system 248 receives information from the measurement system 247 and directs and controls electrical current to the coil units 254 of the stage mover 244 to precisely position the stage 240 and the device 242 based at least in part on the information from the measurement system 247. The control system 22 can include one or more processors. It should be understood that when the stage assembly 236 is part of the exposure apparatus 10, the control system 248 that is provided as part of the stage assembly 236 can be included as part of the control system 24 (illustrated in FIG. 1) of the exposure apparatus 10.

As provided herein, the control system 248 controls the stage mover 244 that moves the stage 240. For example, the control system 248 can use the measurement signals provided from the measurement system 247 to determine the position and velocity of the stage 240 at each of the time instances for which a measurement signal is generated. Additionally, the control system 248 can generate force and torque commands required to move the stage 240 as desired with the stage mover 244 based on the determined position and velocity information for the stage 240, as well as the desired trajectory of the stage 240.

Unfortunately, in some situations, as noted above, the measurement signals can be lost and the exact position of the stage 240 is thus unknown. In such situations, to inhibit the stage 240 from flying off the reaction assembly 246 and/or the stage base 238, or from otherwise losing control, it is desired to arrest the motion of the stage 240 as quickly as possible and in a controlled manner.

In certain embodiments, the control system 248 can arrest the motion of the stage 240 when the measurement signals have been lost by estimating an estimated position and estimated velocity of the stage 240. As described herein, the estimated position and estimated velocity of the stage 240 can be estimated using the most recently determined position and velocity information for the stage 240 (i.e. before the measurement signals were lost), along with the most recent force and torque commands that have been generated by the control system 248. In other words, the position and velocity of the stage 240 can be estimated by dead reckoning or a similar method.

Accordingly, as provided in greater detail herein below, when metrology is lost within the stage assembly 236 and the exact position of the stage 240 is unknown, the control system 248 can be effectively utilized to estimate the position and velocity of the stage 240 using past information. Additionally, the estimated position and velocity of the stage 240 can subsequently be utilized by the control system 248 to generate force and torque commands to quickly and effectively arrest the motion of the stage 240. With such design, the control system 248 is able to inhibit any damage that might otherwise result from a stage with an unknown position and velocity that is moving in an out of control manner.

It should be appreciated that although the discussion of various embodiments of the control system 248 below assume operation in the digital control realm, through an interrupt service routine, such teachings can be easily adjusted for purposes of a purely linear and/or continuous-domain control method.

FIG. 3 is a schematic illustration of an embodiment of a control system 348 usable as part of the stage assembly 236 of FIG. 2. More particularly, the control system 348 can be utilized for controlling the stage mover 244 (illustrated in FIG. 2) that moves the stage 240 (illustrated in FIG. 2). Moreover, as discussed in detail below, the control system 348 can be utilized for quickly and effectively arresting the motion of the stage 240 in situations where measurement signals are lost and the precise, actual position and velocity of the stage 240 are unknown.

As illustrated in FIG. 3, from left to right, the input block 358 provides an input signal 360, e.g., a position reference or trajectory control signal that indicates a desired trajectory for a stage 362. Next, the control system 348 receives a measurement signal 364, provided by the measurement system 247 (illustrated in FIG. 2) that relatives the present position and/or movement of the stage 362. As noted above, the measurement system 247 monitors the position and/or movement of the stage 362 at a plurality of alternative time instances, and, thus, generates such measurement signals 364 at each of the alternative time instances. Additionally, as noted above, the control system 348 can use the measurement signals 364 to determine the position and velocity of the stage 362 at each of the alternative time instances.

As further shown in FIG. 3, the input signal 360, e.g., the desired trajectory, is combined with the measurement signal 364 to form an error signal 366 that represents the difference between the measured position and the desired position. The error signal 366 is subsequently input to a controller 368, which, in turn, generates controller command 369 (e.g. a force command and/or a torque command) for moving the stage 362 as desired. Stated in another manner, the control system 348 via the controller 368 generates the controller command 369 based on the determined position and velocity information for the stage 362, along with the desired trajectory of the stage 362. As is well known in the art, the controller 368 may implement a PID control system or another type of control law.

In certain embodiments, as shown, the controller command 369 is sent to a commutator 370, which generates one or more current command signals 371 for the stage mover 244. The commutator 370 uses the controller commands 369 to generate the proper current command signals 371 for moving the stage 362. The current command signals 371 generated by the commutator 370 are sent to a drive module 372 (e.g., a power amplifier) that directs the appropriate current 375 (motor control signal) to the conductor array 374 of the stage mover 244. Stated in another fashion, the drive module 372 generates the mover control signal 375 (typically an electrical current) for driving each phase of the conductor array 374 of the stage mover 244 to generate the forces that are applied to the stage 362. In certain embodiments, the commutator 370 will also make use of the measured position and/or velocity signal 364 to calculate the current command signals 371.

Additionally, the control system 348 further includes an estimator 376 that helps control the motion of the stage 362 when metrology is lost, i.e. when accurate measurement signals 364 are not available from or being generated by the measurement system 247. More particularly, as detailed herein, in certain embodiments, the estimator 376 is utilized to generate an estimated signal 377 (e.g. an estimated position and/or an estimated velocity) for the stage 362 that is subsequently combined with the input signal 360. In certain embodiments, when current accurate measurement signals 364 have been lost, the input signal 360 can be changed to stop the motion of the stage 362 as quickly as possible. The estimated signal 377 (e.g. the estimated position and/or velocity 377) from the estimator 376 of the stage 362 and the new input signal 360 (to stop the stage 362) are combined to generate the estimated error signal 366, which is again fed through the controller 368 to generate the necessary controller command 369 (referred to as a stop controller command) and the commutator 370 (for generating the necessary current command signals 371) before being sent to the drive module 372. The drive module 372 subsequently generates the mover control signal 375 that is necessary to arrest (stop) the motion of the stage 362.

More specifically, as illustrated in FIG. 3, the measurement signals 364, e.g., from the measurement system 247, in addition to their uses as noted above, are also fed into the estimator 376. In one embodiment, when metrology is lost, the estimator 376 can use one or more of the most recently determined position and velocity information (the last position or velocity information) for the stage 362 (i.e. as determined from the measurement signal 364) as the initial conditions. For example, when metrology is lost, the estimator 376 can use the most recently determined position and velocity information (the last position or velocity information) for the stage 362 (i.e. as determined from the measurement signal 364) as the initial conditions.

In certain embodiments, the estimator 376 can generate the estimated signal 377 (estimated position and/or estimated velocity) of the stage 362 using a mathematical model of the dynamic behavior of the stage 362 (e.g., a simple inertia model), with the most recently determined position and velocity information, and the most recent force and torque commands 369 from the controller 368. Stated in another manner, knowing the previous state (i.e. position and velocity) of the stage 362, and knowing the previous force and torque commands 369 from the controller 368, the estimator 376 calculates a guess for the current state of the stage 362.

In one embodiment, the estimator 376 can estimate of the current state of the stage 362 using simple mass models F=(M×A), and T=(I×alpha), where F is the force command, M is the mass of the stage, A is the acceleration of the stage, T is the torque command, I is the inertia of the stage, and alpha is the angular acceleration of the stage. Mass (M) and inertia (I) can be determined by experimental analysis or approximated by CAD models. Mass and inertia can be referred to as stage parameters of the stage. Additionally, depending on the specific application, the mathematical model of the stage 362 may include other physical stage parameters, such as friction, external disturbances, air drag, or magnetic drag (e.g., eddy current drag) to improve the accuracy of the estimated signal 377.

Based on the estimated signal 377 of the stage 362 as provided by the estimator 376, in combination with the new input signal 360, the controller 368 generates the force and torque commands 369 that are estimated as being required to arrest the motion of the stage 362. These force and torque commands 369 are then fed into the commutator 370, which utilizes the (estimated) force and torque commands 369 to generate the current command signals 371 that are believed necessary to arrest the motion of the stage 362. In most embodiments, the commutator 370 will also make use of the estimated position and/or velocity signal 377 to calculate the current command signals 371. The current command signals 371 are then fed into the drive module 372, which generates the mover control signal 375 that is believed necessary to arrest the motion of the stage 362. When the mover control signal 375 is applied to the stage mover 244, it can then be estimated how this further reduces the velocity of the stage 362 (i.e. how close the velocity of the stage gets to zero) during a subsequent use of this control loop. With this subsequent estimation, further (estimated) force and torque commands 369 can be generated such that the stage 362 is quickly brought to rest in a controlled manner.

As noted above, a primary advantage of the present invention is that through open-loop control actuation of the conductor array 374 of the stage mover 244, the stage 362 can be brought to a halt nearly as fast as would be possible under full feedback control. This greatly mitigates the risk of running into something important near the stage 362 when metrology is lost. During the period while the stage 362 is moving and the position and/or velocity are being estimated by estimator 376, the error signal 366, the current command signals 371, and the mover control signal 375 will not be perfect, but they will be sufficiently accurate to stop the stage 362, typically in a small fraction of a second.

FIG. 4 is a schematic illustration of another embodiment of a control system 448 usable as part of the stage assembly of FIG. 2. The control system 448 illustrated in FIG. 4 is somewhat similar to the control system 348 illustrated and described above in relation to FIG. 3. For example, the control system 448 again includes an input 458 for receiving and/or providing an input signal 460, and a measurement signal 464 generated from the measurement system 247 (illustrated in FIG. 2), that are combined to generate an error signal 466 that is fed into a controller 468. Additionally, the controller 468 again generates a controller command 469 (e.g. force command and/or torque command) for moving the stage 462 as desired, which are based on the determined position and velocity information for the stage 462, along with the desired trajectory of the stage 462. Further, the controller command 469 is again sent to a commutator 470, which generates one or more current command signals 471 for the stage mover 244 (illustrated in FIG. 2). Still further, the current command signals 471 are again sent to a drive module 472 or amplifier for driving the conductor array 474 of the stage mover 244, with the drive module 472 then generating a mover control signal 475 for driving each phase of the stage mover 244 to move the stage 462.

However, in this embodiment, the control system 448 further includes an estimator 476 that functions slightly different than in the previous embodiment, as well as an observer 478. It should be appreciated that although the estimator 476 and the observer 478 are illustrated as being separate entities within the control system 448 in FIG. 4; in certain alternative embodiments, the estimator 476 and the observer 478 can be combined into a single unit within the control system 448.

As shown in FIG. 4, the controller command 469 (force and torque commands) from the controller 468 are not only fed into the commutator 470, but the controller command 469 is also fed into the observer 478. Additionally, the observer 478 can also receive an acceleration signal 479 that indicates the acceleration of the stage 462. In one, non-exclusive embodiment, the acceleration signal 479 can be generated through the use of a differentiator 480 that receives and differentiates the measurement signal 464. Alternatively, the control system 448 can further employ the use of an acceleration sensor (not illustrated) positioned on the stage 462 to measure the acceleration of the stage 462. In an alternative embodiment, the input to the observer 478 may include position and/or velocity information of the stage 462 instead of the acceleration signal 479.

Having received the force and torque commands 469 from the controller 468, as well as the acceleration signal 479, the observer 478 is then able to use a mathematical model, e.g., the simple mass models F=(M×A), and T=(I×alpha), as described above, to calculate accurate one or more stage parameters 482 (e.g. physical parameter information) for the stage 462 (e.g., mass and inertia). As shown in FIG. 4, the stage parameter information 482 is then fed from the observer 478 into the estimator 476. In alternative embodiments, the mathematical model of the stage 462 may include other stage parameters, such as friction, external disturbances, air drag, or magnetic drag (e.g., eddy current drag), and the observer 478 can calculate accurate coefficients or parameters for these effects as additional components of the physical parameter information 482.

As shown, the estimator 476 receives the measurement signals 464, e.g., from the measurement system 247, as well as the stage parameter information 482 from the observer 478. When metrology is lost, the estimator 476 can use the most recently determined position and velocity information for the stage 462 (i.e. as determined from the measurement signal 464), along with the physical parameter information 482 for the stage 462, to estimate an estimated signal 477 (e.g. estimated position and/or an estimated velocity) of the stage 462.

As with the previous embodiment, the estimated signal 477 of the stage 462, as estimated by the estimator 476, is combined with the input signal 460, i.e. the new input signal 460 which encompasses the desire to arrest the motion of the stage 462 as quickly as possible. The combined signal from the estimated signal of the stage 462 and the new input signal 460 is again fed through the controller 468 (for generating the necessary force and torque commands 469) and the commutator 470 (for generating the necessary current command signals 471) before being sent to the drive module 472. The drive module 472 subsequently generates the mover control signal 475 that is believed necessary to arrest the motion of the stage 462. Accordingly, the control system 448 is able to quickly and effectively arrest the motion of the stage 462 in a controlled manner, thus inhibiting any potential damage that may otherwise occur due to the loss of the measurement signal 464.

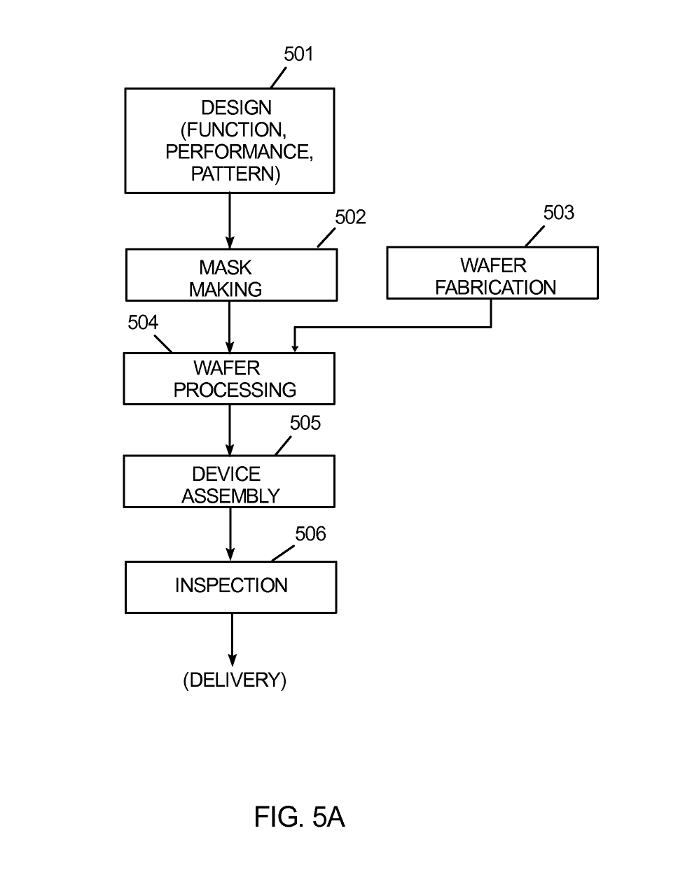

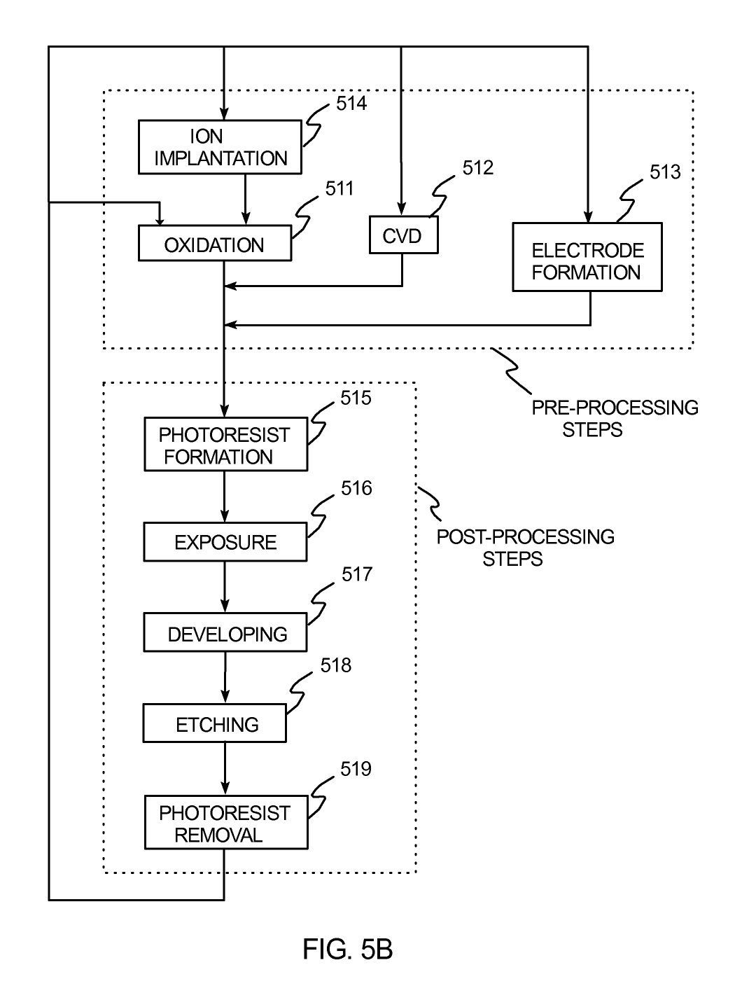

Semiconductor devices can be fabricated using the above described systems, by the process shown generally in FIG. 5A. In step 501 the device's function and performance characteristics are designed. Next, in step 502, a mask (reticle) having a pattern is designed according to the previous designing step, and in a parallel step 503 a wafer is made from a silicon material. The mask pattern designed in step 502 is exposed onto the wafer from step 503 in step 504 by a photolithography system described hereinabove in accordance with the present invention. In step 505 the semiconductor device is assembled (including the dicing process, bonding process and packaging process), finally, the device is then inspected in step 506.

FIG. 5B illustrates a detailed flowchart example of the above-mentioned step 504 in the case of fabricating semiconductor devices. In FIG. 5B, in step 511 (oxidation step), the wafer surface is oxidized. In step 512 (CVD step), an insulation film is formed on the wafer surface. In step 513 (electrode formation step), electrodes are formed on the wafer by vapor deposition. In step 514 (ion implantation step), ions are implanted in the wafer. The above mentioned steps 511-514 form the preprocessing steps for wafers during wafer processing, and selection is made at each step according to processing requirements.

At each stage of wafer processing, when the above-mentioned preprocessing steps have been completed, the following post-processing steps are implemented. During post-processing, first, in step 515 (photoresist formation step), photoresist is applied to a wafer. Next, in step 516 (exposure step), the above-mentioned exposure device is used to transfer the circuit pattern of a mask (reticle) to a wafer. Then in step 517 (developing step), the exposed wafer is developed, and in step 518 (etching step), parts other than residual photoresist (exposed material surface) are removed by etching. In step 519 (photoresist removal step), unnecessary photoresist remaining after etching is removed.

Multiple circuit patterns are formed by repetition of these preprocessing and post-processing steps.

In yet another embodiment, the control system 248 can arrest the motion of the stage 240 when the measurement signals have been lost by controlling the stage mover 244 to urge the stage 240 downward against the coil units 254. It should be noted that the control system 248 can control the force in which the stage 240 is urged downward against coil units 254 to achieve the desired stopping distance.

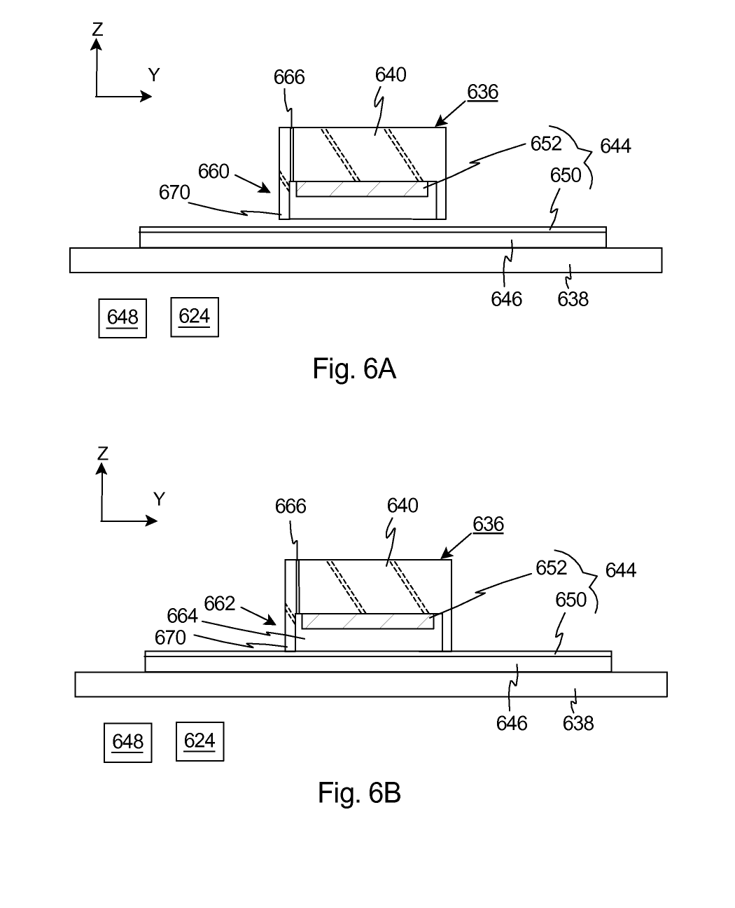

FIG. 6A is a simplified cut-away view of a portion of the stage assembly 636 in an elevated position 660, and FIG. 6B is a simplified cut-away view of the portion of the stage assembly of FIG. 6A in a stopped position 662. The stage 640, the reaction mass 646, the stage base 638, and the stage mover 644 including the conductor array 650 and the magnet array 652, are also illustrated in FIGS. 6A and 6B. The reaction mass 646 and the stage base 638 can be referred to as the base assembly.

In this embodiment, when it is desired to stop the stage 240 quickly (e.g. because of loss of measurement signal), the control system 624 can control the fluid system 648 to create a vacuum between the stage 640 and the reaction mass 646 of the base assembly that urges the stage 640 against the reaction mass 646 via the conductor array 650 to halt relative movement.

Alternatively, the vacuum can be on all the time and the stage mover 644 can be turned off (or controlled so Z force reduced) so that the vacuum pulls the stage 640 against the conductor array 650 connected to the reaction mass 646. In this design, the vacuum can also remove heat generated by the stage mover 644 during normal operation.

Still alternatively, the stage mover 644 can be controlled to urge the stage 640 against the reaction mass 646, via the conductor array 650 connected to the reaction mass 646, to quickly halt relative movement. In this embodiment, the control system 624 can direct the appropriate current to the conductor array 650 to generate a downward Z force on the stage 640 that urges the stage 640 against the conductor array 650.

Further, the control system 624 can use electromagnetic force (by shorting the coils/conductors of the conductor array 650) to brake the stage 640 by converting the kinetic energy to heat. Stated in another fashion, the conductor array 650 is closed by the control system 624, and the induced electromotive force due to the changing magnetic field sets up a current and this energy is lost as heat in coils of the conductor array. With the present design, the vacuum is used to greatly increase the braking force to inhibit the stage 640 from crashing into important components (for example a metrology arm (not shown)). Thus, the problem of large stopping distance due to low braking force using only Coil/Eddy Current braking is solved by using vacuum in the base of the stage 640 to increase friction force and thus reduce braking distance.

As provided herein, when the stage 640 lands on the conductor array 650 attached to the reaction mass 646, a small vacuum chamber 664 is created at the bottom of the stage 640. Further, the fluid system 648 (e.g. a vacuum pump) controlled by the control system 624 will apply a vacuum via a vacuum inlet 666 to the vacuum chamber 664 to apply a force that attracts the stage 640 towards the base assembly 646. This attractive force helps increase the friction force between the stage 640 and the base assembly 646 (the friction force along a surface is proportional to the normal force between the contacting surfaces). As a non-exclusive example, the increase in normal force for a 0.8 m×0.6 m stage 640 is about thirty-two times compared to the case without this vacuum chamber 664. If the stage were stopped only by using friction then the stopping distance will reduce by approximately thirty-two times. However the eddy current drag is also used to stop the stage.

In one embodiment, the vacuum chamber 664 can be created by having a skirt 670 that is positioned around, cantilevers downward, and encircles the magnets 652 at a bottom side on the stage 640.

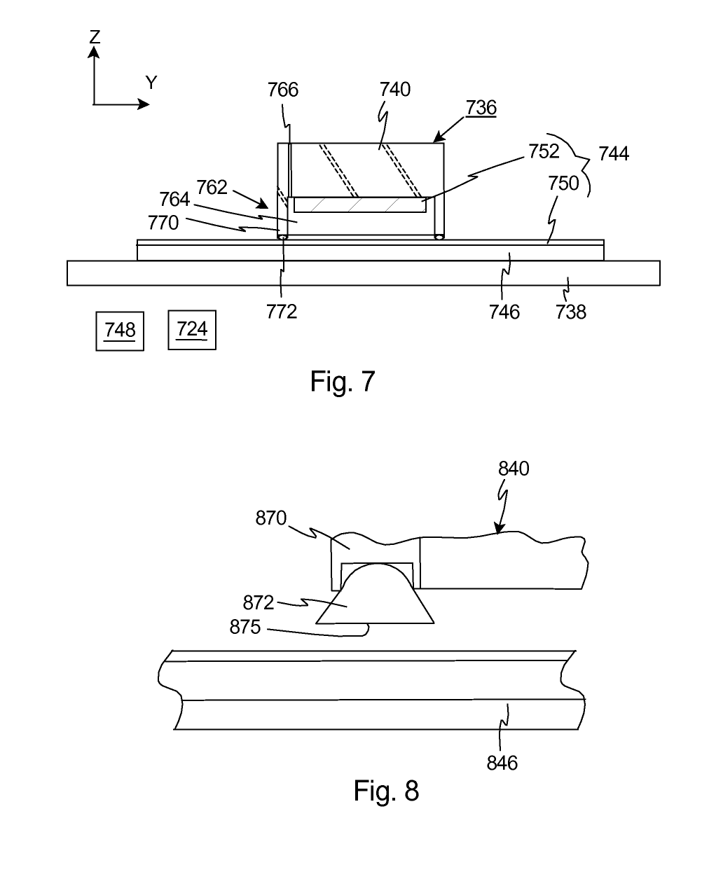

FIG. 7 is a simplified cut-away view of a portion of another embodiment of the stage assembly 736 in the stopped position 762. The stage mover 744 including the stage 740, the conductor array 750 and the magnet array 752, the reaction mass 746, and the stage base 738 are also illustrated in FIG. 7.

In this embodiment, the vacuum chamber 764 is again created by having a skirt 770 around the bottom (including the magnets 752) of the stage 740. This skirt 770 can also be possibly lined with rubber like material 772 (e.g. a seal) to create a good seal between the stage 740 and the base assembly 746. For example, a bottom of the skirt 770 can include an O ring type seal that seals the vacuum chamber 764 to the base assembly 746. In certain embodiments, with this design, the contact area of the skirt 770 is made of a material having a relatively high coefficient of friction with the base assembly 746.

In one, non-exclusive embodiment, in addition to providing a way to quickly stop the stage 740, the chamber 764 can also be used as an “emergency air hover” system. With this design, the fluid source 748 can be controlled by the control system 724 to direct pressurized fluid into the chamber 764 to hover the stage 740 above the conductor array 750 attached to the reaction mass 746.

In certain embodiments, the skirt 770 needs to extend only a small amount beyond the magnets 752 in order to provide for a space for vacuum layer.

FIG. 8 is a simplified illustration of a portion of another embodiment of the skirt 870 of the stage 840, the seal 872, and the base assembly 846 with the stage 840 spaced apart from the base assembly 846. In this embodiment, these components are somewhat similar to the corresponding components described above and illustrated in FIG. 7. However, in this embodiment, the seal 872 is uniquely designed to have an enlarged contact area 875 that selectively engages the base assembly 846 when the stage 840 is urged towards the base assembly 846. This enlarged contact area will further inhibit relative movement between the stage 840 and the base assembly 846. In certain embodiments, the enlarged contact area 875 has a contact surface that is made of a material having a relatively high coefficient of friction with the base assembly 846. For example, the contact surface can be made of rubber, and the contact surface can be secured to the stage 840 with a rigid frame.

The size of the enlarged contact area 875 can be varied to achieve the desired stopping results. As non-exclusive examples, the enlarged contact area 875 can increase the contact area at least approximately 10, 20, 30, 40, 50, 60, 70, 80, 90, 100, or larger percent when compared to a design without the enlarged contact area.

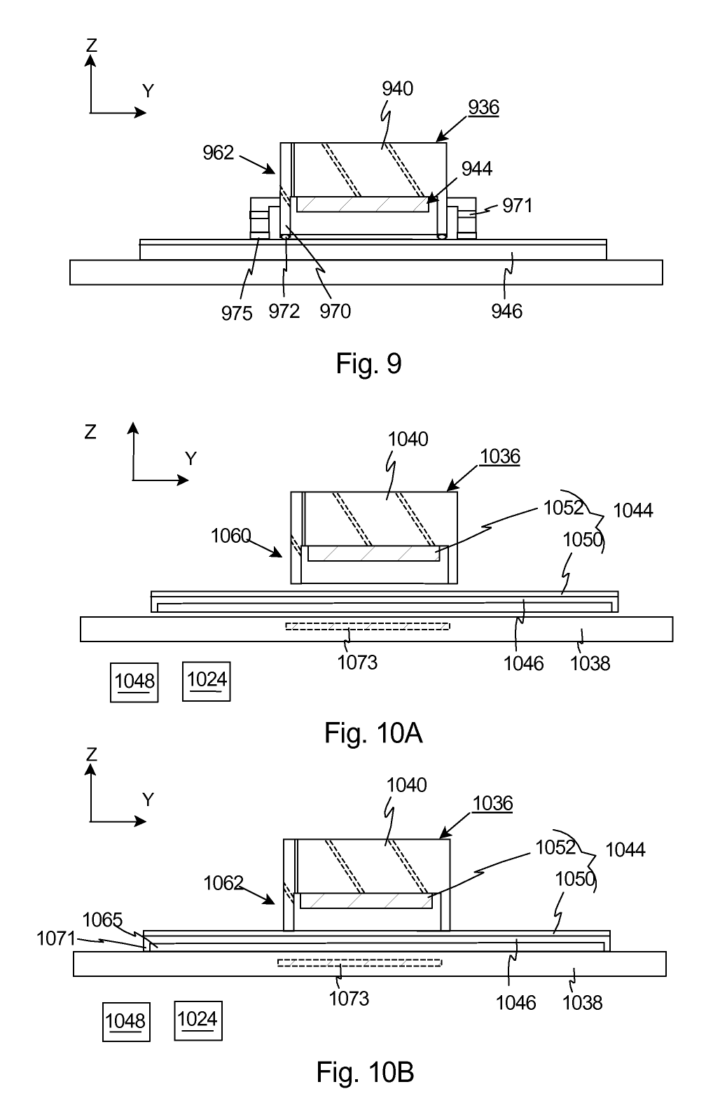

FIG. 9 is a simplified cut-away view of a portion of another embodiment of the stage assembly 936 in the stopped position 962. In this embodiment, the stage assembly 936 includes the stage mover 944, the stage 940, and the base assembly 946 that are similar to the corresponding components described above and illustrated in FIG. 7. However, in this embodiment, the stage 940 includes one or more enlarged contact areas 975 that are secured to the stage 940 and that cantilever away from the stage. In this embodiment, the contact area(s) 975 engage the base assembly 946 (via the conductor array) when the stage 940 is urged towards the base assembly 946 to provide a relatively large contact area 975 to inhibit relative movement between the stage 940 and the base assembly 946.

In one embodiment, the enlarged contact area 975 is an enlarged, annular, rectangular shaped member that encircles the outer perimeter of the skirt 970. Alternatively, the enlarged contact area 975 can be positioned within and be encircled by the skirt 970. Still alternatively, enlarged contact area 975 can be divided into a plurality of separate contact areas 975 that are distributed around the stage 940. As non-exclusive examples, the enlarged contact area 975 can increase the contact area at least approximately 10, 20, 30, 40, 50, 60, 70, 80, 90, 100, or larger percent when compared to a design without the enlarged contact area.

In certain embodiments, the enlarged contact area 975 has a contact surface that is made of a material having a relatively high coefficient of friction with the base assembly 946. For example, the contact surface can be made of rubber, and the contact surface can be secured to the stage 940 with a rigid frame.

In another embodiment, the contact areas 975 can be actuated up and down (via air or electrical motor 971) to cause contact. Further, the bottom of the stage can be covered in rubber or other high coefficient of friction material to stop the stage quickly.

FIG. 10A is a simplified cut-away view of a portion of another embodiment of the stage assembly 1036 in an elevated position 1060, and FIG. 10B is a simplified cut-away view of the portion of the stage assembly 1036 of FIG. 10A in a stopped position 1062. In this embodiment, the stage assembly 1036 is somewhat similar to the stage assembly 1036 described above and illustrated in FIG. 10A. However, in this embodiment the reaction mass 1046 (e.g. the countermass) is slightly different. The stage mover 1044 including the stage 1040, the conductor array 1050 and the magnet array 1052, the reaction mass 1046, and the stage base 1038 are also illustrated in FIGS. 10A and 10B. The reaction mass 1046 and the stage base 1038 can collectively be referred to as a reaction assembly.

In this embodiment, when it is desired to stop the stage 1040 quickly, the control system 1024 can control the fluid system 1048 to create (i) a vacuum between the stage 1040 and the reaction mass 1046 (via the conductor array 1050) that urges the stage 1040 against the conductor array 1050 to halt relative movement; and (ii) a vacuum between the reaction mass 1046 and the stage base 1038 that urges the reaction mass 1046 against the stage base 1038 to halt relative movement. With the present design, the vacuum is used to greatly increase the braking force to inhibit the reaction mass 1046 from moving relative to the stage base 1038.

During normal operation, a fluid bearing can be used to support the reaction mass 1046 relative to the stage base 1038. With this design, the fluid bearing allows for movement of the reaction mass 1046 relative to the stage base 1038.

As provided herein, when the reaction mass 1046 lands on the stage base 1038, a small vacuum chamber 1065 is created at the bottom of the reaction mass 1046. Further, the fluid system 1048 (e.g. a vacuum pump) controlled by the control system 1024 will apply a vacuum to the vacuum chamber 1065 to apply a force that attracts the reaction mass 1046 towards the stage base 1038. This attractive force helps increase the friction force between the reaction mass 1046 and the stage base 1038 (the friction force along a surface is proportional to the normal force between the contacting surfaces). The vacuum chamber 1065 can be created by having a skirt 1071 that is positioned around and encircles the bottom of the reaction mass 1046. Alternatively, a mover 1073 (illustrated in phantom) can be controlled to inhibit relative motion of the reaction mass 1046 relative to the stage base 1038.

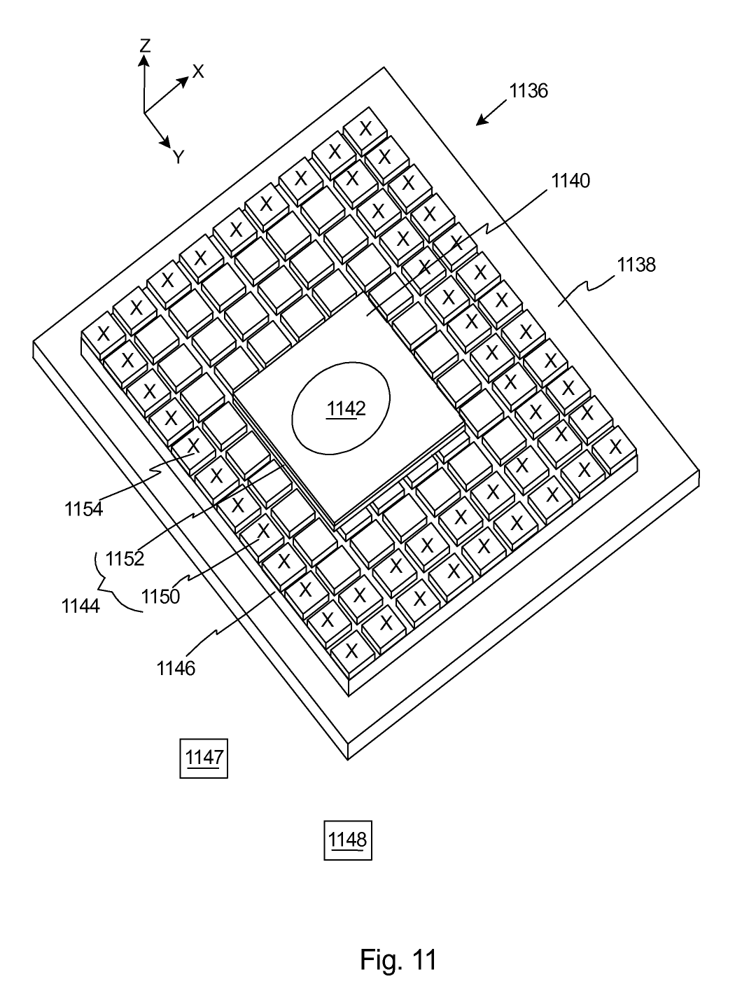

FIG. 11 is a perspective view of an embodiment of a stage assembly 1136 having features of the present invention. In this embodiment, the stage assembly 1136 includes a stage base 1138, a stage 1140 that retains a device 1142, a stage mover 1144 including a magnet array 1152 and a conductor array 1150, a countermass reaction assembly 1146 (also referred to herein simply as a “reaction assembly” or “reaction mass”), a measurement system 1147 (illustrated as a box), and a control system 1148 (illustrated with a box) that are similar to the corresponding components described above and illustrated in FIG. 2. However, in this embodiment, the control system 1148 continuously directs current to one or more of the coil units 1154 for braking only.

More specifically, during many usages, the desired trajectory of the stage 1140 is known. Thus, it will be known if certain coil units 1154 will not be needed to move the stage 1140 along the known trajectory. These unneeded coil units 1154 (also referred to as “repelling coil units”) can be controlled and used as a brake to inhibit the stage 1140 from being moved past the desired trajectory. In the non-exclusive example illustrated in FIG. 11, the unneeded coil units 1154 are indicated with an “X”. With this design, the control system 1148 can always directed current to one or more of the unneeded coil units 1154 with such a commutation phase that they will always “repel” the edge magnets of the magnet array 1152 thereby providing protection from a runaway stage 1140 situation.

The exact coil units 1154 used to repel the stage 1140 can be varied and changed to suit the trajectory requirements of the stage 1140 and to protect the components near the stage 1140.

In one embodiment, the control system 1148 continuously directs current to the repelling coil units during the movement of the desired trajectory. Alternatively, the control system 1148 can be designed to direct current to the repelling coil units only when the measurement signal is lost. With either design, the control system directs current to one or more coil units of the stage mover to repel the stage 1140 and inhibit the stage 1140 from moving off the desired trajectory.

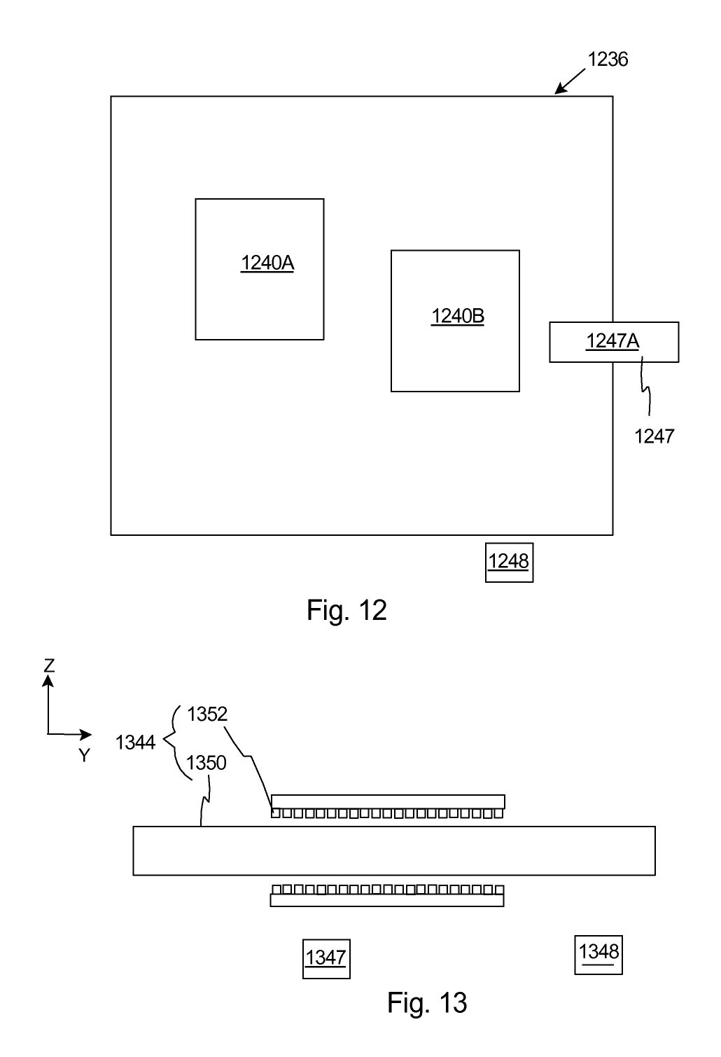

FIG. 12 is a simplified top view of another embodiment of a stage assembly 1236 that is somewhat similar to the stage assembly 236 described above and illustrated in FIG. 2. However, in this embodiment, the stage assembly 1236 includes two independently movable stages 1240A and 1240B. Further, a metrology arm 1247A of the measurement system 1247 is also illustrated in FIG. 12. The metrology arm 1247A can include one or more encoders or interferometers. In one embodiment, when the measurement signal is lost, the control system 1248 controls the movements of the stages 1240A, 12408 to quickly stop, and to avoid collisions with each other and the metrology arm 1247A. Any of the methods provided above can be used to achieve these goals.

FIG. 13 is a simplified side view of another embodiment of a stage mover 1344 (that can be coupled to a stage), a measurement system 1347, and a control system 1348. In this embodiment, the stage mover 1344 again includes a magnet array 1352 and a conductor array 1350. However, in this embodiment, the stage mover 1344 is a linear mover and one array is moved relative to the other array along a single axis (e.g. the Y axis). Moreover, in this embodiment, the control system 1348 can again be used to stop the stage mover 1344 by one of the methods provided above, in the event the measurement signal from the measurement system 1347 is lost.

While a number of exemplary aspects and embodiments of a stage assembly 236 and control system 248 have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are within their true spirit and scope.

What is claimed is:

1. A method for controlling a stage mover that moves a stage along a desired trajectory, the method comprising the steps of:
monitoring a position of the stage at a plurality of alternative time instances with a measurement system that generates a measurement signal for each time instance;
controlling the stage mover with a control system, the control system generating a controller command based on the measurement signal and the desired trajectory; and
estimating an estimated signal of the stage with the control system using a previous measurement signal in the event the measurement system fails to provide the measurement signal.

2. The method of claim 1 further comprising the step of, in the event the measurement system fails to provide the measurement signal, calculating a stop controller command at each of the time instances necessary to stop the stage with the control system using the estimated signal, and controlling the stage using the stop controller command.

3. The method of claim 2 wherein the step of estimating includes the step of using a previous controller command along with the previous measurement signal to provide the estimated signal.

4. The method of claim 3 wherein the step of estimating includes the step of using a mathematical model of the stage to provide the estimated signal.

5. The method of claim 2 wherein the control system changes back to normal operation if the measurement system resumes operation.

6. The method of claim 2 wherein the measurement signal corresponds to at least one of a position, a velocity, and an acceleration of the stage.

7. The method of claim 1 wherein the step of estimating includes the step of using a mathematical model of the stage to provide the estimated signal.

8. The method of claim 7 further comprising the step of using an observer to calculate at least one stage parameter for the mathematical model during normal control of the stage, and wherein the step of estimating includes using the at least one stage parameter to provide the estimated signal.

9. The method of claim 8 wherein the at least one stage parameter includes at least one of a mass of the stage or an inertia of the stage.

10. The method of claim 8 wherein the at least one stage parameter includes at least one of a viscous drag of the stage, a mechanical friction of the stage, disturbance forces from cables and/or hoses connected to the stage, an air drag of the stage, a magnetic drag of the stage, and other external disturbances of the stage.

11. The method of claim 1 wherein the step of controlling includes the control system controlling the stage mover to urge the stage against a base assembly to stop the stage in the event the measurement system fails to provide the measurement signal.

12. A stage assembly for positioning a workpiece along a desired trajectory, the stage assembly comprising:
a stage that retains the workpiece;
a stage mover that moves the stage and the workpiece;
a measurement system that generates a separate measurement signal that relates to a position of the stage at each of a plurality of alternative time instances; and
a control system that controls the stage mover, the control system generating a controller command based on the measurement signal and the desired trajectory; wherein, the control system estimates an estimated signal of the stage using a previous measurement signal in the event the measurement system fails to provide the measurement signal.

13. The stage assembly of claim 12 wherein the control system uses a previous controller command along with the previous measurement signal to provide the estimated signal.

14. The stage assembly of claim 12 wherein the control system uses a mathematical model of the stage to provide the estimated signal.

15. The stage assembly of claim 14 wherein the control system includes an observer that calculates at least one stage parameter for the mathematical model during normal control of the stage, and wherein the control system uses the stage parameter to provide the estimated signal.

16. The stage assembly of claim 12 wherein, in the event the measurement system fails to provide the measurement signal, the control system calculates a stop controller command at each of the time instances necessary to stop the stage using the estimated signal, and control system controls the stage using the stop controller command.

17. A method for controlling a stage mover that moves a stage along a desired trajectory, the method comprising the steps of:
monitoring a position of the stage at a plurality of alternative time instances with a measurement system that generates a measurement signal for each time instance; and
controlling the stage mover with a control system, the control system generating a controller command based on the measurement signal and the desired trajectory; wherein, in the event of loss of the measurement signal, controlling the stage mover with the control system to stop the stage.

18. The method of claim 17 wherein the step of controlling includes the control system controlling the stage mover to urge the stage against a base assembly to stop the stage.

19. The method of claim 17 wherein the control system changes back to normal operation if the measurement system resumes operation.

20. The method of claim 17 further comprising the step of coupling an enlarged contact area to the stage, wherein the contact area engages a base assembly when the stage is urged towards the base assembly to provide a relatively large contact area to inhibit relative movement between the stage and the base assembly.

21. The method of claim 17 wherein the step of controlling includes the control system controls a fluid system to create a vacuum between the stage and a base assembly to urge the stage against the base assembly.

22. The method of claim 17 wherein the step of controlling includes the control system controls the stage mover to provide coil/eddy current braking of the stage to stop the stage assembly.

23. The method of claim 17 wherein the step of controlling includes the control system closing a conductor circuit of a conductor assembly of the stage mover.

24. The method of claim 17 further providing the step of coupling a flexible skirt around a bottom of the stage.

25. The method of claim 17 further comprising the steps of coupling a reaction mass to the mover assembly, supporting the reaction mass relative to a stage base, and in the event of loss of the measurement signal, urging the reaction mass against the stage base.

26. The method of claim 17 wherein the step of controlling includes the control system directing current to one or more coil units of the stage mover to inhibit the stage from moving off the desired trajectory.
